(19) United States
(12) Patent Application Publication
(10) Pub. No.: US 2010/0002389 A1
(43) Pub. Date: Jan. 7, 2010

(54) FAN FASTENER

(75) Inventors: Chia-Ming Tung, Jhong Ho City (TW); Yung-Lin Hsu, Jhong Ho City (TW)

Correspondence Address: PAI PATENT & TRADEMARK LAW FIRM, 1001 FOURTH AVENUE, SUITE 3200, SEATTLE, WA, 98154, US

(73) Assignee: XIGMATEK CO., LTD., Jhong Ho City (TW)

(21) Appl. No.: 12/165,657

(22) Filed: Jul. 1, 2008

(51) Int. Cl. H05K 7/20

(52) U.S. Cl. 361/697

(57) ABSTRACT

An elastic, rod-like fan fastener for securing a heat sink cooling fan to a heat sink is disclosed having a head at one end, a positioning rod comprising an extension rod at the opposite end, a first shank segment axially connected between the head and the extension rod, and a second shank segment axially connected between the first shank segment and the extension rod, a neck axially connected between the head and the first shank segment, a shoulder extending around the periphery between the neck and the first shank segment, and a plurality of barbed portions extending around the periphery of the positioning rod and spaced along the length of the positioning rod.

### BACKGROUND OF THE INVENTION

(a) Field of the Invention

The present invention relates to cooler modules and, more particularly, to a fan fastener for connection between a heat sink cooling fan of various types and a heat sink.

(b) Description of the Prior Art

A conventional heat sink cooling fan comprises a fan housing and a motor fan. During installation, screws are inserted through tubular columns or mounting through holes of the fan housing and then fastened to the heat sink to secure the heat sink cooling fan to the heat sink. During operation, the heat sink cooling fan may vibrate, causing noise. Vibration of the heat sink cooling fan during operation may affect component parts' positioning stability and their functioning.

### SUMMARY OF THE INVENTION

The present invention has been accomplished under the circumstances in view. It is therefore the main object of the present invention to provide a fan fastener for securing a heat sink cooling fan to a heat sink, which prevents vibration of the heat sink cooling fan during its operation, avoiding noise problem. It is another object of the present invention to provide a fan fastener for securing a heat sink cooling fan to a heat sink. The fan fastener can fit various types of heat sink cooling fans.

To achieve these and other objects of the present invention, the fan fastener is made of an elastic material in the shape of a rod member for securing a heat sink cooling fan to a heat sink. The fan fastener comprises a head at one end; a positioning rod comprising an extension rod at the opposite end, a first shank segment axially connected between the head and the extension rod, and a second shank segment axially connected between the first shank segment and the extension rod; a neck axially connected between the head and the first shank segment; a shoulder extending around the periphery between the neck and the first shank segment; and a plurality of barbed portions extending around the periphery of the positioning rod and spaced along the length of the positioning rod. By means of the barbed portions, the fan fastener can be fastened to any of various types of heat sink cooling fans securely. After installation, the excessive part that extends out of the back side of the heat sink cooling fan can be cut off. By means of the head and the shoulder, the fan fastener can be fastened to a heat sink, securing the heat sink cooling fan to the heat sink. When the heat sink cooling fan is in operation, it does not vibrate, reducing the noise level.

### BRIEF DESCRIPTION OF THE DRAWINGS

FIG. 1 is an exploded view of a heat sink cooling fan and fan fasteners according to the present invention.

FIG. 2 corresponds to FIG. 1, showing installation of the fan fastener in the heat sink cooling fan according to the present invention.

FIG. 3 is a front view of a fan fastener in accordance with a first embodiment of the present invention.

FIG. 4 is a side view of FIG. 3.

FIG. 5 illustrates installation of fan fasteners in another structure of heat sink cooling fan according to the present invention.

FIG. 6 illustrates fan fasteners installed in a heat sink cooling fan before connection to a heat sink according to the present invention.

FIG. 7 is an assembly view of FIG. 6.

FIG. 8 is a schematic plain view showing installation of the fan fastener in a heat sink according to the present invention (I).

FIG. 9 is a schematic plain view showing installation of the fan fastener in a heat sink according to the present invention (II).

FIG. 10 is a schematic plain view showing installation of the fan fastener in a heat sink according to the present invention (III).

FIG. 11 is an elevational view of a fan fastener in accordance with a second embodiment of the present invention.

FIG. 12 shows an application example of the second embodiment of the present invention.

### DETAILED DESCRIPTION OF THE PREFERRED EMBODIMENTS

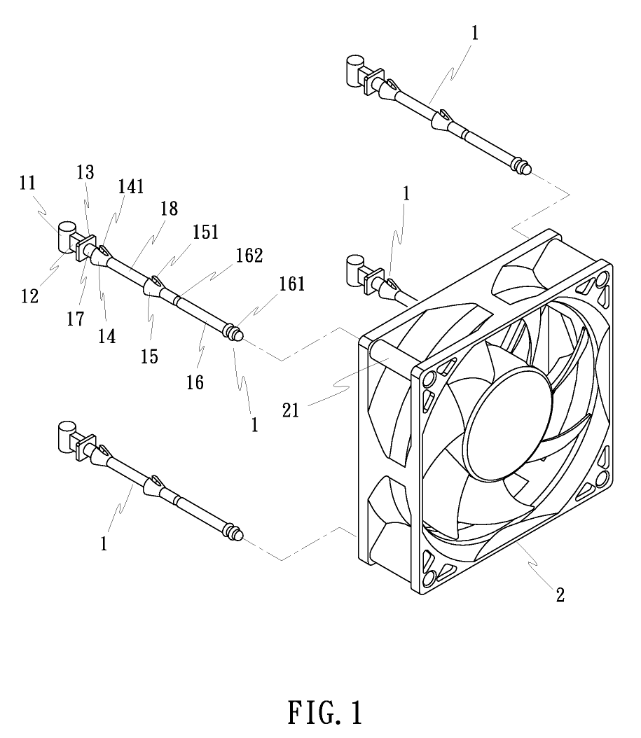

Referring to FIGS. 1˜4, a fan fastener 1 in accordance with a first embodiment of the present invention is a fastening rod member made of rubber, silicon rubber, or any elastic material, comprising a head 11 at one end; a positioning rod comprising an extension rod 16 at the other end, a first shank segment 17 axially connected between the head 11 and the extension rod 16, and a second shank segment 18 axially connected between the first shank segment 17 and the extension rod 16; a neck 12 axially connected between the head 11 and the first shank segment 17; a shoulder 13 extending around the periphery between the neck 12 and the first shank segment 17; and at least one barbed portion placed around the periphery of the positioning rod and spaced along the length of the positioning rod. For example, the at least one barbed portion can be the two barbed portions 14 and 15 extending around the periphery between the first shank segment 17 and the second shank segment 18, and around the periphery between the second shank segment 18 and the extension rod 16, respectively. However, it is emphasized that the barbed portions can be placed anywhere along the length of the fastening rod (namely, the first shank segment 17, second shank segment 18 and the extension rod 16) according to the size and the type of the heat sink cooling fan 2 to be fastened.

The head 11 is a block having a predetermined configuration—for example, a cylindrical shape. The cylindrical head 11 is perpendicularly connected to the neck 12.

The neck 12 is a flat rectangular block. The flat rectangular neck 12 extends in a direction parallel to the axis of the cylindrical head 11.

The shoulder 13 has the shape of a flat block extending in a direction perpendicular to the neck 12 and the first shank segment 18.

The barbed portions 14 and 15 are shaped like truncated cones. The distance between the two barbed portions 14 and 15 fits the length of the tubular columns 21 between the front and back panels of a heat sink cooling fan 2 to be installed. Furthermore, each barbed portion 14 or 15 has a transversely extending through hole 141 or 151.

The extension rod 16 has finger collars 161 extending around the periphery near the distal end (free end) convenient for grasping with the fingers, and a breaking portion 162 near the proximal end (the end connected to the rear barbed portion 15). The breaking portion 162 has a relatively smaller thickness than the extension rod 16 so that it can easily be broken.

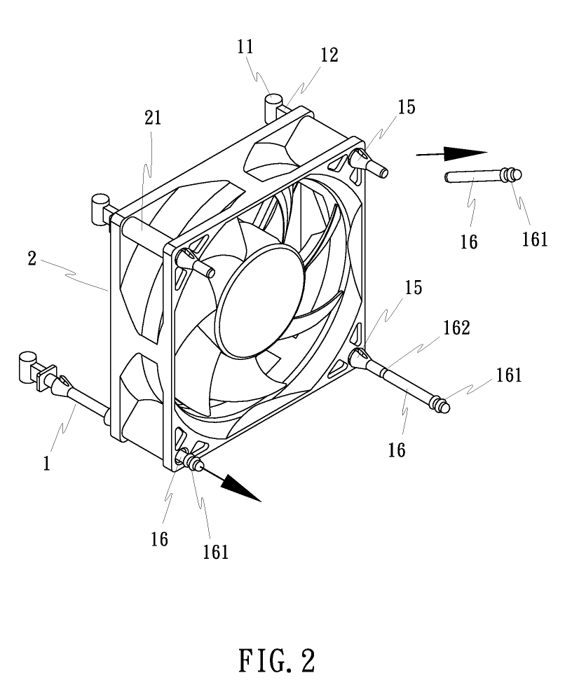

Referring to FIG. 2, the fan fastener 1 can be inserted through one tubular column 21 between the front and back panels of a heat sink cooling fan 2 to have the rear barbed portion 15 be stopped at the back side of the back panel of the heat sink cooling fan 2.

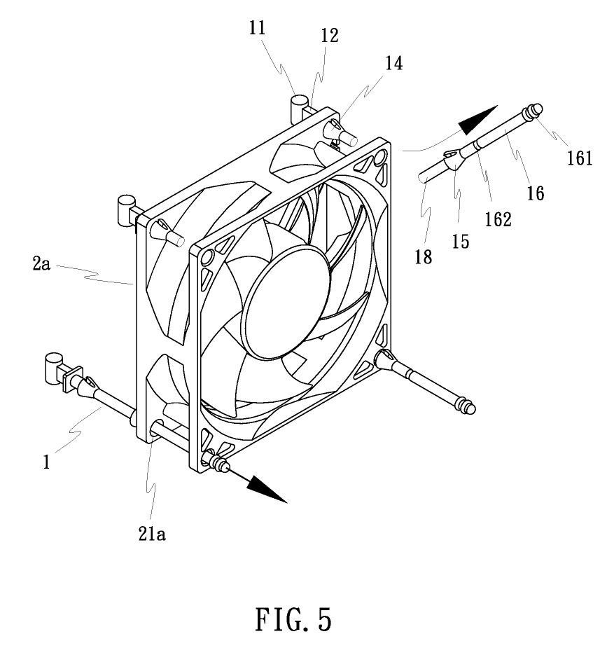

Referring to FIG. 5, the fan fastener 1 can be inserted through one respective mounting through hole 21a on each of the front and back panels of another structure of heat sink cooling fan 2a to have the front barbed portion 14 be stopped at the back side of the front panel of the heat sink cooling fan 2 and the rear barbed portions 15 be stopped at the back side of the back panel of the heat sink cooling fan 2.

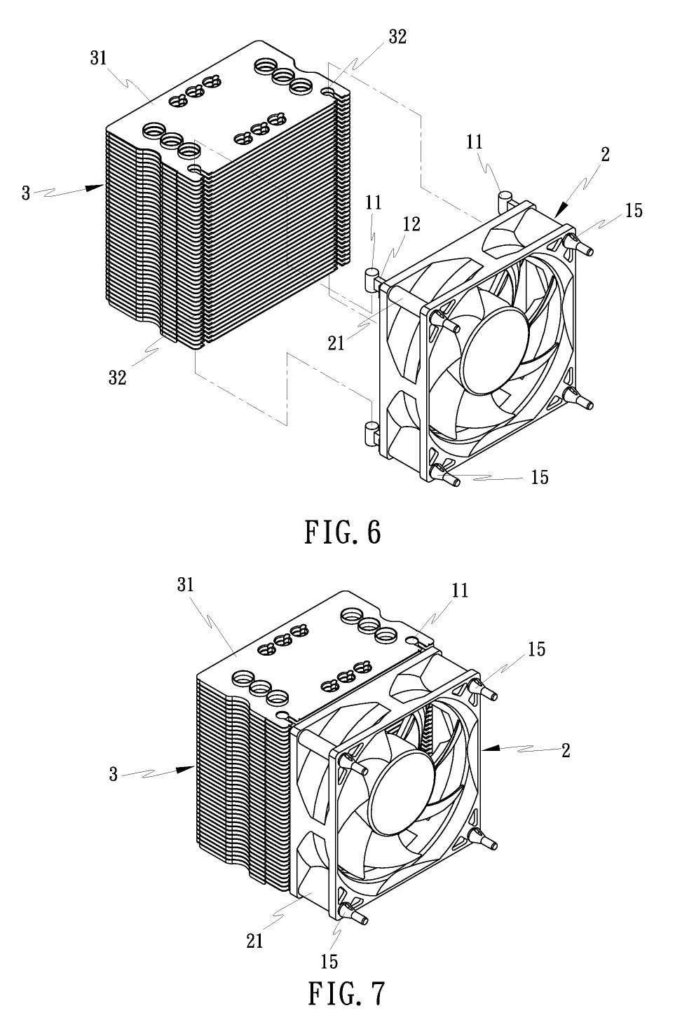

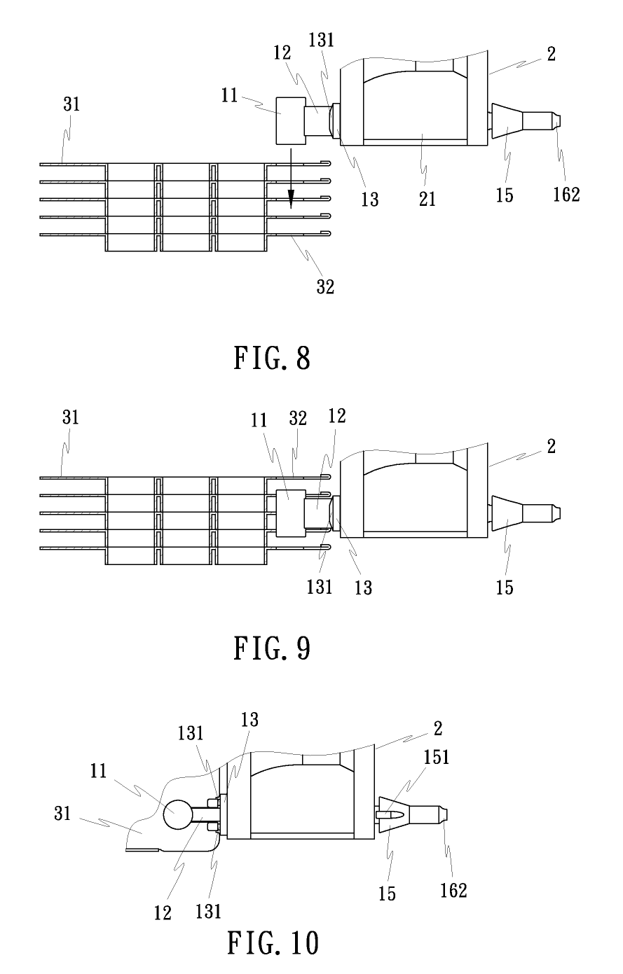

After installation of multiple fan fasteners 1 in the heat sink cooling fan 2 (or 2a), the heat sink cooling fan 2 (or 2a) can then be fastened to a heat sink 3 by means of the fan fasteners 1 (see FIGS. 6 and 7).

By means of the through holes 141 and 151, the barbed portions 14 and 15 are highly compressible so that the fastener 1 can easily be inserted through the tubular columns 21 or the mounting through hole 21a.

Furthermore, the design of the barbed portions 14 and 15 makes the fan fastener 1 applicable to various types of heat sink cooling fans 2 and 2a.

For use with the heat sink cooling fan 2 shown in FIGS. 1 and 2, the fan fastener 1 is inserted through one tubular column 21 between the front and back panels of a heat sink cooling fan 2 to have the shoulder 13 be stopped at the front side of the front panel of the heat sink cooling fan 2 and the rear barbed portion 15 be stopped at the back side of the back panel of the heat sink cooling fan 2, and then the breaking portion 162 is broken to separate the extension rod 16 from the fan fastener 1. After installation of four fan fasteners 1 in the four tubular columns 21 of the heat sink cooling fan 2, the heat sink cooling fan 2 is fastened to a heat sink 3 by means of the fan fastener 1.

Referring to FIGS. 6˜10, the heat sink 3 is comprised of a stack of radiation fins 31. Each radiation fin 31 has two keyway-shaped mounting notches 32 bilaterally extended to one side. After installation of four fan fasteners 1 in the heat sink cooling fan 2, the heads 11 of the fan fasteners 1 are respectively inserted into the expanded portions of the keyway-shaped mounting notches 32 of the radiation fins 31, thereby securing the heat sink cooling fan 2 to the heat sink 3.

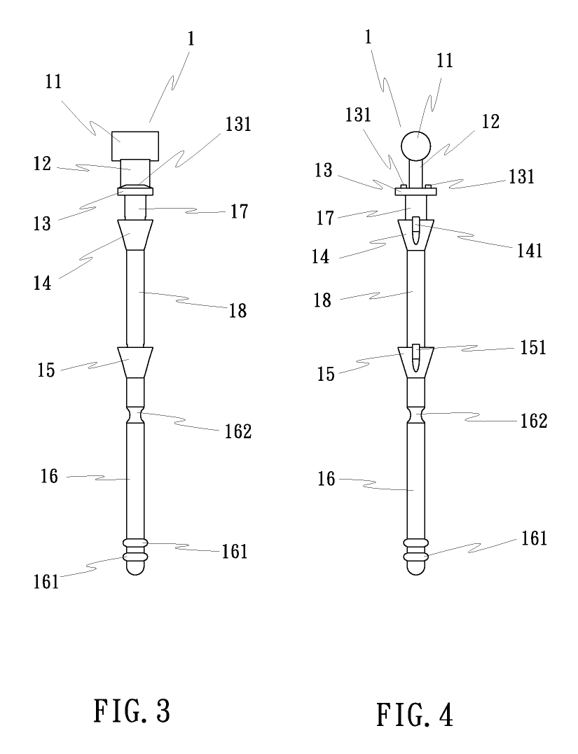

Referring to FIGS. 3 and 4, the shoulder 13 has a plurality of ribs 131 protruding from its one side, namely, the top side thereof. After insertion of the head 11 into vertically aligned keyway-shaped mounting notches 32 of the heat sink 3, the ribs 131 are stopped against the edge of the respective radiation fins 31 (see FIGS. 7 and 9).

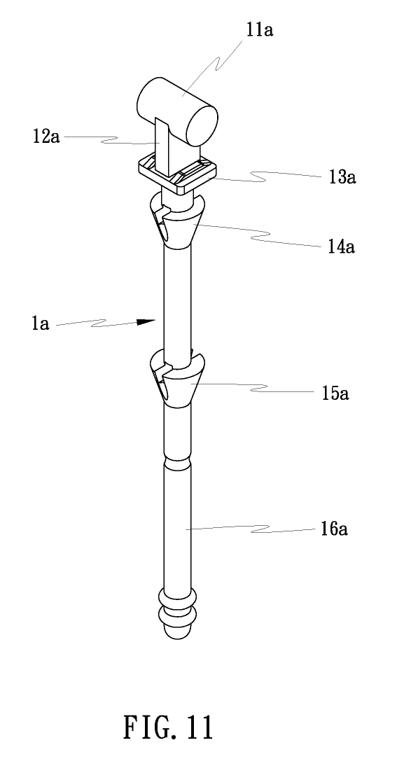

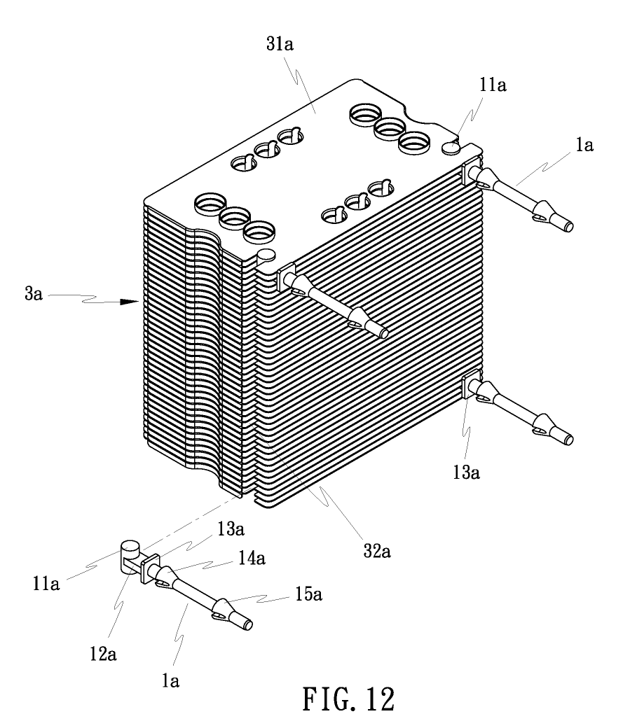

FIG. 11 shows a fan fastener 1a in accordance with a second embodiment of the present invention. This second embodiment is substantially similar to the aforesaid first embodiment with the exception that the flat rectangular neck 12a extends in a transverse direction that is perpendicular to the extending direction of the cylindrical head 11a. This design is to match the heat sink 3a of which each radiation fin 31a has the two mounting notches 32a respectively formed on two opposite edges.

Although particular embodiments of the invention have been described in detail for purposes of illustration, various modifications and enhancements may be made without departing from the spirit and scope of the invention.

What is claimed is:

1. A fan fastener for securing a heat sink cooling fan to a heat sink, said fan fastener being made of an elastic material in a rod-like shape and comprising:
a head disposed at one end thereof;
a positioning rod comprising an extension rod disposed at an opposite end thereof, a first shank segment axially connected between said head and said extension rod, and a second shank segment axially connected between said first shank segment and said extension rod;
a neck axially connected between said head and said first shank segment;
a shoulder extending around a periphery between said neck and said first shank segment; and
a plurality of barbed portions extending around a periphery of said positioning rod and spaced along the length of said positioning rod.

2. The fan fastener as claimed in claim 1, wherein said head is a cylindrical block member.

3. The fan fastener as claimed in claim 2, wherein said neck extends from said head in a longitudinal direction relative to said head.

4. The fan fastener as claimed in claim 2, wherein said neck extends from said head in a transverse direction relative to said head.

5. The fan fastener as claimed in claim 1, wherein said neck is a flat rectangular block.

6. The fan fastener as claimed in claim 1, wherein said barbed portions have the shape of a truncated cone.

7. The fan fastener as claimed in claim 1, wherein the distance between two adjacent barbed portions is smaller than the length between front and back panels of a housing of the heat sink cooling fan to be fastened.

8. The fan fastener as claimed in claim 1, wherein each said barbed portion has a transversely extending through hole.

9. The fan fastener as claimed in claim 1, wherein said extension rod has at least one finger collar extending around a distal end remote from said second shank segment and a breaking portion having a reduced diameter disposed adjacent to said second shank segment.
